(19) United States
(12) Patent Application Publication
(10) Pub. No.: US 2018/0092251 A1
(43) Pub. Date: Mar. 29, 2018

(54) Server Cooling System Capable of Performing a Two-Phase Immersion Typed Heat Dissipation Process

(71) Applicants: Inventec (Pudong) Technology Corp., Shanghai (CN); Inventec Corporation, Taipei (TW)

(72) Inventors: Kai-Yang Tung, Taipei (TW); Hung-Ju Chen, Taipei (TW)

(21) Appl. No.: 15/472,267

(22) Filed: Mar. 28, 2017

(30) Foreign Application Priority Data
Sep. 29, 2016 (CN) 201610866139.3

(51) Int. Cl. H05K 7/20

(52) U.S. Cl. CPC H05K 7/20309; H05K 7/20809; H05K 7/20336; H05K 7/20318; H05K 7/20418; H05K 7/20327

(57) ABSTRACT

A server cooling system includes a container, a heat dissipation device, and a housing. The container is used for containing non-conductive fluid. An electronic device is completely soaked in the non-conductive fluid to cool down. The heat dissipation device is disposed above the container for cooling vapor generated from the non-conductive fluid. The housing covers the container and the heat dissipation device for forming an enclosed space. When the temperature of the electronic device is higher than a vaporization temperature of the non-conductive fluid, the non-conductive fluid is vaporized gradually. After the vapor reaches the heat dissipation device, the vapor is condensed to become condensed fluid. The condensed fluid is then dropped to the container so as to cool the non-conductive fluid to be below the vaporization temperature.

### BACKGROUND OF THE INVENTION

### 1. Field of the Invention

The present invention illustrates a server cooling system, and more particularly, the server cooling system using vaporization and condensation of non-conductive fluid for dissipating heat.

### 2. Description of the Prior Art

With advancement of techniques, various electrical devices with high operational performance are widely adopted. Nowadays, most electrical devices are required to perform high processing speed and low response time in conjunction with a high-level processor integrated to a micro volume circuit. Thus, the electrical devices can be operated by users at any time and in any place. For example, the specification of iPhone 5s states that an A7-typed processor is used. The specification of iPhone 6 Plus states that an A8-typed processor is used. Another example is that the central processing unit (CPU) of the personal computer is upgraded from Intel® Core™ i5 to Intel® Core™ i7. Specifically, power consumption and heat generation of the electrical device are increased since the clock frequency of the processor is increased. Thus, performance of heat dissipation components such as heat dissipation fans, thermally conductive adhesives, and heat sinks attracts more attention. Among these heat dissipation devices, thermally conductive adhesives and heat sinks have smaller volume with inferior heat dissipation performance since they only use a medium for conducting heat. As a result, heat dissipation fans (hereafter say, cooling fans) become the most popular devices for dissipating heat in general electric devices.

In general, the cooling fans can generate enforced air convection by rotating fan blades for dissipating heat. In other words, the heat is transferred from a heat source to ambient air through the air convection. However, since a specific heat value of air is quite small, performance of heat dissipation is not satisfactory. To improve the performance of heat dissipation, high revolutions per minute (RPM) is required to the cooling fan for enhancing air convection, thereby leading to power consumption. Further, the cooling fan generally includes a mechanical motor. When the cooling fan is operated under high RPM, operational noise is also increased.

Nowadays, data transmission by using virtual machines through network is popularly used in a cloud computing server and a data center system. Thus, the cloud computing server or the data center system is required to deal with numerous data and perform high data rate transmission. To achieve high performance, the cloud computing server generally uses a processor with a very high frequency and a memory device with a high density and capacity. As a result, requirement of heat dissipation efficiency in the cloud computing server is stricter than other electronic devices. Further, since numerous circuit modules and components are disposed inside the cloud computing server with a very high density, a space of air convection inside the server is reduced. Thus, the heat dissipation efficiency in the cloud computing server by using cooling fan-based method is insufficient.

### SUMMARY OF THE INVENTION

In an embodiment of the present invention, a server cooling system is disclosed. The server cooling system comprises a container, a heat dissipation device, and a housing. The container is configured to contain non-conductive fluid for cooling down an electronic device soaked in the non-conductive fluid. The heat dissipation device is disposed above the container and configured to cool vapor generated from the non-conductive fluid. The housing is configured to enclose the container and the heat dissipation device in order to form an enclosed space. When a temperature of the electronic device exceeds a vaporization temperature of the non-conductive fluid, the non-conductive fluid is vaporized gradually. The vapor is condensed to become condensed fluid after the vapor reaches the heat dissipation device. The condensed fluid is dropped to the container so as to cool the non-conductive fluid to be below the vaporization temperature and to stabilize a depth of the non-conductive fluid.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a structure of a server cooling system according to an embodiment of the present invention.

FIG. 2 is a structure of a heat dissipation device of the server cooling system in FIG. 1.

FIG. 3 is a structure including a filter pump, a first pipe, and a second pipe of the server cooling system in FIG. 1.

FIG. 4 is a structure of a molecular sieve of the server cooling system in FIG. 1.

### DETAILED DESCRIPTION

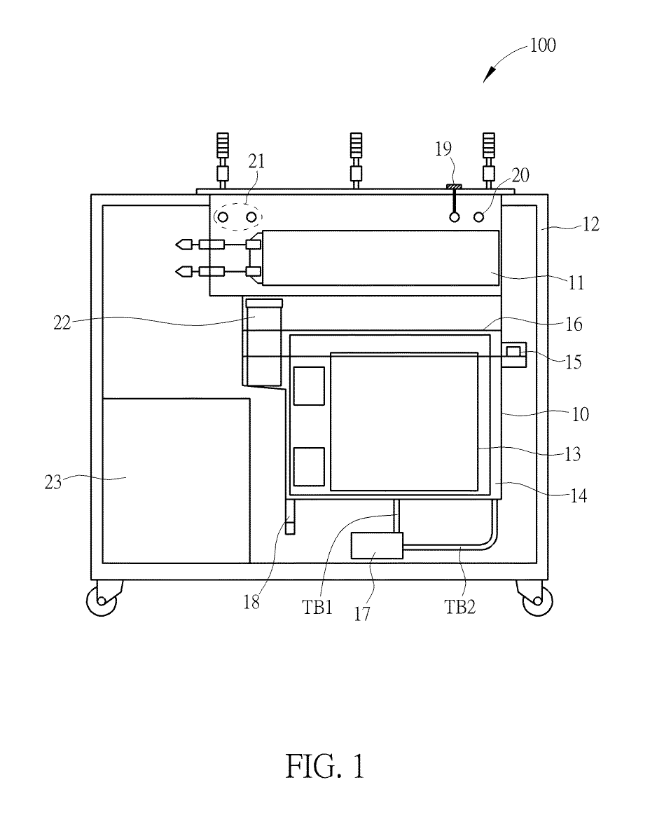

FIG. 1 is a structure of a server cooling system 100 according to an embodiment of the present invention. Since the server cooling system 100 uses a housing 12 to enclose most of components, an appearance of the server cooling system 100 can be a cuboid or a cylinder. For illustrating the structure of the server cooling system 100 in detail, FIG. 1 presents a sectional view of the server cooling system 100. The server cooling system 100 includes a container 10, a heat dissipation device 11, and the housing 12. The container 10 can be a metallic container or a nonmetallic container. The container 10 has a space for containing non-conductive fluid 14. Specifically, the non-conductive fluid 14 is defined as fluid with electrical conductance substantially equal to zero, such as non-conductive refrigerant or mineral oil. The electronic device 13 can be regarded as a heat source. The electronic device 13 is completely soaked in the non-conductive fluid 14. In other words, after the electronic device 13 is completely soaked in the non-conductive fluid 14, a depth of the non-conductive fluid 14 is greater than a height of the electronic device 13 (i.e., a liquid level 16 of the non-conductive fluid 14 is higher than the height of the electronic device 13). The electronic device 13 can be any electronic heat source. For example, the electronic device 13 can include a motherboard, a central processing unit, a solid state disk, and/or a memory of a server. The heat dissipation device 11 is disposed above the container 10 for cooling down vapor generated from the non-conductive fluid 14. A principle of heat dissipation in the server cooling system 100 is described below. When the electronic device 13 generates heat by consuming driving power, a temperature of the electronic device 13 is increased. When the temperature of the electronic device 13 exceeds a vaporization temperature of the non-conductive fluid 14, the non-conductive fluid is vaporized gradually and thus generates vapor with high temperature. Specifically, latent heat of the vapor is greater than latent heat of the fluid. After the vapor reaches the heat dissipation device 11, heat of vaporization can be removed from the vapor. Thus, the vapor (i.e., gaseous state) is condensed to be condensed fluid (i.e., liquid state). When the weight of the condensed fluid is high enough, the condensed fluid is naturally dropped to the container 10. In the embodiment, a boiling temperature of the non-conductive fluid 14 is around 40 degrees Celsius to 70 degrees Celsius for increasing an inlet temperature of the heat dissipation device 11. When the non-conductive fluid is vaporized under a boiling effect (i.e., an intense vaporization) and/or a convectional effect to dissipate heat from the electronic device 13, no power is required in the heat dissipation device 11. As a result, when the appropriate non-conductive fluid 14 is used, total power consumption of the server cooling system 100 can be reduced.

In the embodiment, the electronic device 13 can be a server or partial integrated circuit of the server. As known, the server is required to deal with numerous data and perform high data rate transmission. To achieve high performance, the server generally uses a processor with a very high frequency and a memory device with a high density and capacity. Thus, numerous circuit modules and components are disposed inside the server with a very high density. A space of air convection inside the server is reduced. If conventional cooling fan-based method is applied to the server for dissipating heat, heat dissipation efficiency is insufficient. In other words, the server cooling system 100 capable of performing a two-phase immersion typed heat dissipation process is appropriately applied to cool the server.

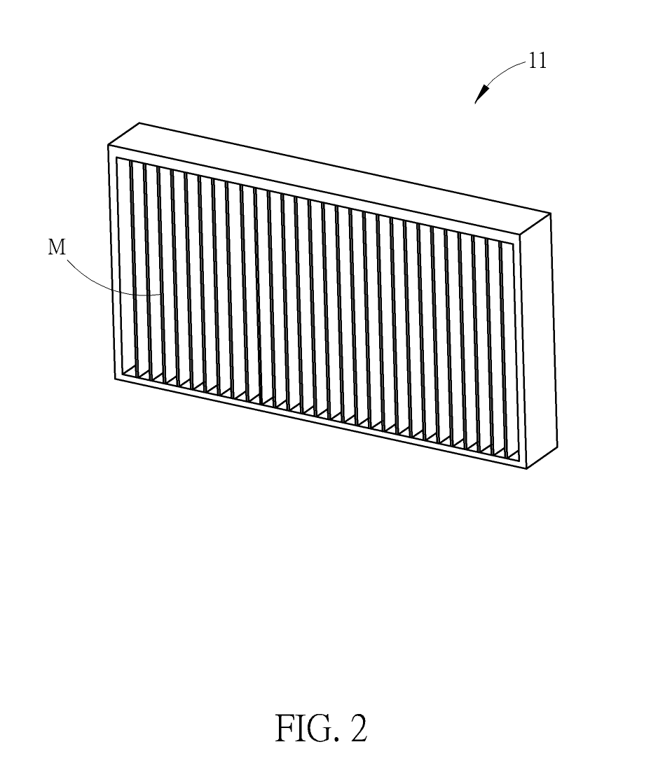

The heat dissipation device 11 of the server cooling system 100 can be a condenser, as shown in FIG. 2. FIG. 2 is a structure of the heat dissipation device 11 of the server cooling system 100. When the heat dissipation device 11 is considered as the condenser, it includes a plurality of metal fins M. The plurality of metal fins M can maximize a contact area between air and the heat dissipation device 11 for improving heat dissipation performance. In the heat dissipation device 11, the plurality of metal fins M can be arranged in a shape of parallel, a shape of mesh, a shape of concentric circles, or any geometric shape capable of maximizing the contact area. The heat dissipation device 11 can also introduce a water-cooling pipe to dissipate heat from the plurality of metal fins M. By using the heat dissipation device 11, the heat of vaporization can be removed from the vapor. As a result, latent heat of the condensed fluid dropped to the container 10 can be reduced. Thus, a temperature of the non-conductive fluid 14 can be controlled to be smaller or equal to the vaporization temperature. Further, the housing 12 is used for enclosing the container 10 and the heat dissipation device 11 as illustrated in FIG. 1. Thus, the housing 12 can form an enclosed space. In the server cooling system 100, the housing 12 is essential since the housing 12 can avoid the vapor generated from the non-conductive fluid 14 to leak to the ambient air. As a result, the depth of the non-conductive fluid 14 can be stabilized. Note that the housing 12 can be a metallic housing or a nonmetallic housing.

In the server cooling system 100, the non-conductive fluid 14 becomes the vapor through vaporization. Then, the vapor becomes the condensed fluid and is dropped to the container 10. Specifically, a convectional cycle between the vapor (gaseous state) and the condensed fluid (liquid state) is regarded as a two-phase natural convectional cycle of substance. As a result, since the heat dissipation process of the electronic device 13 can be naturally and automatically performed in the server cooling system 100, no additional power or driving circuit is required. In other words, the server cooling system 100 can be categorized as a two-phase immersion typed cooling system. Further, the non-conductive fluid 14 is defined as fluid with electrical conductance substantially equal to zero. A specific heat value of the non-conductive fluid 14 is greater than a specific heat value of the air. Thus, the non-conductive fluid 14 can use a boiling effect and/or a convectional effect for removing heat from the electronic device 13. A principle is illustrated below. When the non-conductive fluid 14 on the surface of the electronic device 13 has an extremely intense vaporization, such as a boiling effect, the vapor of the non-conductive fluid 14 can remove lots of heat from the electronic device 13 in a short time. Further, when the boiling effect of the non-conductive fluid 14 occurs, the convectional effect is also enhanced. As a result, the convectional cycle (i.e., between the gaseous state and the liquid state) is also boosted, thereby increasing the heat dissipation performance.

To further improve the heat dissipation performance and security of the server cooling system 100, several optional modules can be introduced. Functions and utilities of the modules are illustrated later.

To improve the security of the server cooling system 100, a liquidometer 15 can be introduced, as shown in FIG. 1. The liquidometer 15 is disposed on the container 10. For example, an adhesion method can be used for disposing the liquidometer 15 on inner or outer surface of the container 10. The liquidometer 15 can be used for detecting a liquid level 16 of the non-conductive fluid 14. Specifically, the liquidometer 15 can be any device capable of detecting liquid level. For example, the liquid level 16 can be detected by using a ball float meter, a probe meter, or an ultrasonic meter. As aforementioned illustration, in the server cooling system 100, the electronic device 13 is completely soaked in the non-conductive fluid 14. Thus, the liquid level 16 is higher than the electronic device 13 under a normal condition. However, the liquid level 16 may be detected as an abnormal liquid level by the liquidometer 15 when one of the following abnormal conditions occurs. In the first abnormal condition, when the electronic device 13 has an abnormally high temperature, the temperature of the non-conductive fluid 14 is rapidly increased. At the moment, lots of non-conductive fluid 14 becomes vapor. When the heat dissipation device 11 cannot remove total heat of vaporization carried by massive vapor, quantity of the condensed fluid dropped to the container is insufficient. As a result, the liquid level 16 may be reduced because the vaporization of the non-conductive fluid 14 is too strong. When the liquid level 16 is lower than the electronic device 13, the liquidometer 15 can generate a warning signal. Then, the heat dissipation device 11 tries to enhance the heat dissipation performance. For example, the heat dissipation device 11 can use external cooling fans for enhancing the heat dissipation performance. In the second abnormal condition, when the heat dissipation device 11 is operated under an abnormal state, the heat dissipation device 11 cannot remove total heat of vaporization carried by the vapor. As a result, the quantity of the condensed fluid dropped to the container is also insufficient. Thus, the liquid level 16 is reduced. Particularly, the heat dissipation device 11 may be operated under the abnormal state due to several possible issues. For example, the heat dissipation performance may be greatly reduced because the heat-conductive materials or metal fins of the heat dissipation device 11 are deteriorated or rusted. Similarly, when the liquid level 16 is lower than the electronic device 13, the liquidometer 15 can generate the warning signal. Then, the heat dissipation device 11 can be replaced with a new one.

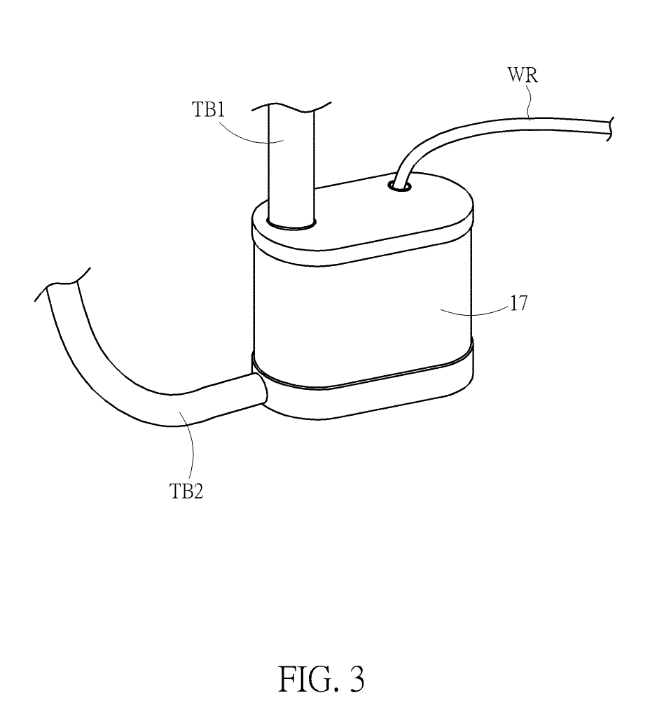

To avoid the electronic device 13 being damaged by the server cooling system 100, a filter pump 17, a first pipe TB1, and a second pipe TB2 can be introduced to the server cooling system 100. FIG. 3 is a structure including the filter pump 17, the first pipe TB1, and the second pipe TB2 of the server cooling system 100. As aforementioned illustration, the electrical conductance of the non-conductive fluid 14 is substantially equal to zero. However, some dust or stains may be adhered to the electronic device 13. When the electronic device 13 is soaked in the non-conductive fluid 14, the dust or stains may escape from the electronic device 13. In other words, the dust or stains may be suspended in the non-conductive fluid 14. Specifically, the dust or stains have a chance to drift into a core integrated circuit of the electronic device 13. When electrical conductance of the dust or stain is large enough, the circuit of the electronic device 13 may be shorted, thereby leading to irreversible circuit damage. To avoid the electronic device 13 being damaged, the server cooling system 100 can use the filter pump 17, the first pipe TB1, and the second pipe TB2 for filtering the dust or stains. In the server cooling system 100, the first pipe TB1 is connected between the filter pump 17 and the container 10. The second pipe TB2 is connected between the filter pump 17 and the container 10. A wire WR can be used in the filter pump 17 for driving the motor inside the filter pump 17. The filter pump 17 extracts a portion of the non-conductive fluid 14 inside the container 10 through the first pipe TB1. Then, the filter pump 17 filters the portion of the non-conductive fluid 14 for generating filtered non-conductive fluid. In the embodiment, any filtering mechanism can be used in the filter pump 17. For example, the filter pump 17 can use filter meshes for filtering the dust or stains from the portion of the non-conductive fluid 14. Thus, the filter meshes are consumables. In the following, the filter pump 17 injects the filtered non-conductive fluid into the container 10 through the second pipe TB2. Thus, the filter pump 17, the first pipe TB1, and the second pipe TB2 can be regarded as a circulation system for filtering impurities. By doing so, a risk of irreversible circuit damage in the electronic device 13 caused by the dust or stains can be reduced.

To maintain high heat dissipation performance of the server cooling system 100, the non-conductive fluid 14 has to be replaced periodically. For replacing the non-conductive fluid 14, the server cooling system 100 can introduce a discharge valve 18. The discharge valve 18 is disposed outside the container 10 and connected to the container 10 through a hole. Specifically, the discharge valve 18 can be an electronic or non-electronic spigot, or a threaded plug. When a user wants to replace the non-conductive fluid 14 with new fluid, the user can open the discharge valve 18 to release the non-conductive fluid 14 inside the container 10 through the hole.

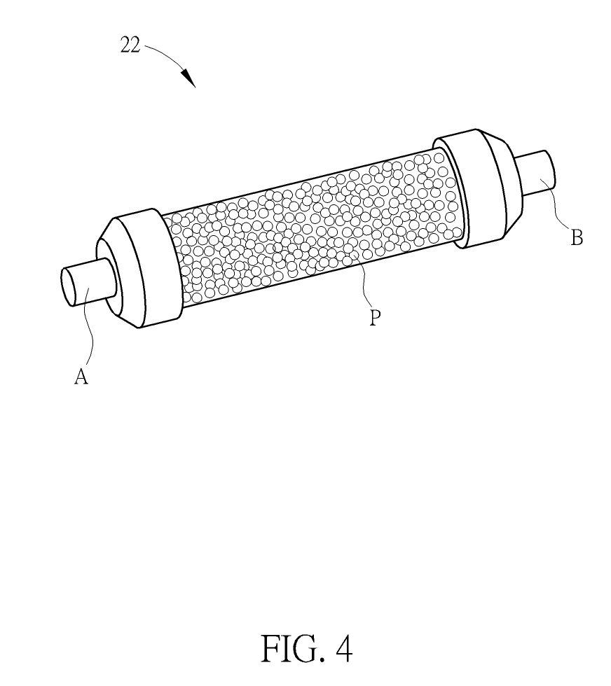

As aforementioned illustration, the server cooling system 100 can introduce the filter pump 17, the first pipe TB1, and the second pipe TB2 for reducing the risk of irreversible circuit damage in the electronic device 13 caused by dust or stains. To further protect the electronic device 13 from triggering short circuit, a molecular sieve 22 can be introduced. In the server cooling system 100, the molecular sieve 22 can be disposed between the container 10 and the heat dissipation device 11. The molecular sieve 22 can absorb moisture inside the housing 12. Although the housing 12 forms an enclosed space, humidity of the enclosed space may not be equal to zero. In other words, some moisture may exist inside the housing 12. Further, some moisture outside the housing 12 may infiltrate to the enclosed space through junctions of the housing 12. Thus, when the non-conductive fluid 14 is mixed with some water molecules, the electrical conductance of the non-conductive fluid 14 is increased. When the electrical conductance of the non-conductive fluid 14 is greater than a threshold of triggering the circuit in a short state, the electronic device 13 is damaged. Thus, the cooling system 100 can use the molecular sieve 22 for absorbing moisture inside the housing 12, thereby decreasing a rising rate of the electrical conductance of the non-conductive fluid 14. FIG. 4 is a structure of the molecular sieve 22 of the server cooling system 100. The molecular sieve 22 includes a port A and a port B. The molecular sieve 22 includes a space inside a shell of the molecular sieve 22. The space is used for filling with dehumidification particles P. Since hydrophilicity of dehumidification particles P is very high, the molecular sieve 22 has a capability for absorbing moisture, especially in medium or low humidity. By using the molecular sieve 22, the humidity of the enclosed space inside the housing 12 can be substantially equal to zero. Specifically, the dehumidification particles P can be nano-molecular particles (MCM-41), Carbon molecular particles (CMSN2), Titanium Silicon particles, or any particles with very high hydrophilicity. As a result, the water molecules of the enclosed space can be absorbed by the dehumidification particles P through the port A and the port B. However, the server cooling system 100 is not limited to using the molecular sieve 22 with two ports. For example, any container including the dehumidification particles P can be applied to the server cooling system 100.

As aforementioned illustration, the non-conductive fluid 14 becomes the vapor through vaporization. Then, the vapor becomes the condensed fluid and is dropped to the container 10 for removing heat from the electronic device 13. However, when the non-conductive fluid 14 becomes the vapor, the corresponding volume (liquid state to gaseous state) is rapidly increased. Since a space inside the housing 12 is the enclosed space, a barometric pressure of the enclosed space is increased when the vaporization of the non-conductive fluid 14 occurs. To monitor the barometric pressure of the enclosed space, a pressure sensing port 20 can be introduced. A relief valve 19 can also be introduced for adaptively controlling the barometric pressure of the enclosed space. Here, the pressure sensing port 20 is disposed inside the housing 12 for sensing the barometric pressure of the enclosed space. The pressure sensing port 20 can be coupled to a pressure meter or any pressure quantization device. A user can observe a value of the barometric pressure of the enclosed space inside the housing 12 by using the pressure meter or any pressure quantization device coupled to the pressure sensing port 20. The relief valve 19 is disposed outside the housing 12 and connected to the enclosed space though an opening. Specifically, the relief valve 19 can be an electronic relief valve or a non-electronic relief valve. When the barometric pressure of the enclosed space is greater than a threshold (i.e., for example, three atms), the relief valve 19 is opened manually or automatically for reducing the barometric pressure of the enclosed space. By doing so, the barometric pressure of the enclosed space is equal to one atm (i.e., barometric pressure outside the housing 12). As a result, since the relief valve 19 can reduce the barometric pressure of the enclosed space, a risk of gas explosion caused by a high barometric pressure inside the housing 12 can be reduced.

Since the electronic device 13 is disposed inside the housing 12 of the server cooling system 100. For operating the electronic device 13 by an external device or a user, an input/output port (I/O port) 21 can be introduced to the server cooling system 100. The I/O port 21 can be disposed on a side of the housing 12. Specifically, the I/O port 21 can be coupled to the electronic device 13 through wired or wireless connections. Thus, the user can control the electronic device 13 through the I/O port 21. As aforementioned illustration, the heat dissipation performance and the barometric pressure of the server cooling system 100 can be automatically controlled. Thus, the server cooling system 100 can also include a controller 23 to optimize operations of the cooling system 100. The controller 23 can be coupled to at least one module of the server cooling system 100, such as the molecular sieve 22, the discharge valve 18, the filter pump 17, the liquidometer 15, the heat dissipation device 11, the pressure sensing port 20 and/or the relief valve 19. In other words, the controller 23 can monitor the humidity, a status of heat dissipation, the barometric pressure and/or the liquid level 16 of the non-conductive fluid 14. When at least one parameter monitored by the controller 23 is abnormal, the controller 23 automatically controls the corresponding module for stabilizing the heat dissipation performance and the barometric pressure of the server cooling system 100. For example, when high barometric pressure of the enclosed space inside the housing 12 is detected by the controller 23 through the pressure sensing port 20, the controller 23 controls the relief valve 19 to reduce the barometric pressure. By using the controller 23, the security of the server cooling system 100 can be improved.

To sum up, the present invention discloses a server cooling system. The server cooling system can be regarded as a two-phase immersion typed cooling system. Specifically, a specific heat value of the non-conductive fluid in the server cooling system is greater than a specific heat value of the air. The server cooling system can use vaporization of the non-conductive fluid for removing heat from a surface of the electronic device even through no external power is used for enforcing convection. When a boiling effect of the non-conductive fluid occurs, the convection of the non-conductive fluid is also enhanced. As a result, the convection of vapor can be enhanced simultaneously. Further, the server cooling system uses the heat dissipation device for removing heat of vaporization from the vapor. Thus, latent heat of the vapor can be reduced. The vapor is then condensed to become condensed fluid and dropped to the container. Further, since a convectional cycle between the vapor (gaseous state) and the condensed fluid (liquid state) is regarded as a two-phase natural cycle of substance, the server cooling system can naturally dissipate heat from the electronic device without additional power.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A server cooling system, comprising:
a container configured to contain non-conductive fluid for cooling down an electronic device soaked in the non-conductive fluid;
a heat dissipation device disposed above the container and configured to cool vapor generated from the non-conductive fluid; and
a housing configured to enclose the container and the heat dissipation device in order to form an enclosed space;
wherein when a temperature of the electronic device exceeds a vaporization temperature of the non-conductive fluid, the non-conductive fluid is vaporized gradually, the vapor is condensed to become condensed fluid after the vapor reaches the heat dissipation device, and the condensed fluid is dropped to the container so as to cool the non-conductive fluid to be below the vaporization temperature and to stabilize a depth of the non-conductive fluid.

2. The system of claim 1, wherein the non-conductive fluid is non-conductive refrigerant, the heat dissipation device is a condenser, and the condenser comprises a plurality of metal fins.

3. The system of claim 1, further comprising a liquidometer disposed on the container and configured to detect the depth of the non-conductive fluid, wherein when the depth is smaller than a height of the electronic device, the liquidometer generates an alarm signal.

4. The system of claim 1, further comprising a filter pump, a first pipe, and a second pipe, wherein the filter pump is disposed inside the housing, the first pipe is connected between the filter pump and the container, the second pipe is connected between the filter pump and the container, the filter pump extracts a portion of the non-conductive fluid inside the container through the first pipe, the filter pump filters the portion of the non-conductive fluid for generating filtered non-conductive fluid, and the filter pump injects the filtered non-conductive fluid into the container through the second pipe.

5. The system of claim 1, further comprising a discharge valve disposed outside the container and configured to release the non-conductive fluid inside the container through a hole.

6. The system of claim 1, further comprising a molecular sieve disposed between the container and the heat dissipation device and configured to absorb moisture inside the housing.

7. The system of claim 1, further comprising a pressure sensing port disposed inside the housing and configured to sense a barometric pressure of the enclosed space.

8. The system of claim 1, further comprising a relief valve disposed outside the housing and connected to the enclosed space though an opening, wherein when a barometric pressure of the enclosed space is greater than a threshold, the relief valve reduces the barometric pressure of the enclosed space.

9. The system of claim 1, further comprising an input/output port (I/O port) disposed on a side of the housing and coupled to the electronic device, and configured to control the electronic device.

10. The system of claim 1, wherein an electrical conductance of the non-conductive fluid is substantially equal to zero, a boiling temperature of the non-conductive fluid is around 40 degrees Celsius to 70 degrees Celsius for increasing an inlet temperature of the heat dissipation device, the non-conductive fluid uses a boiling effect and/or a convectional effect to dissipate heat of the electronic device, and when the non-conductive fluid is boiled, the convectional effect is enhanced.
